(19) United States
(12) Patent Application Publication
(10) Pub. No.: US 2026/0181959 A1
(43) Pub. Date: Jun. 25, 2026

(54) METHOD FOR MANUFACTURING INDIUM MONOSELENIDE SEMICONDUCTOR THIN FILM FOR FABRICATING LARGE-AREA THIN FILM TRANSISTOR

(71) Applicant: POSTECH RESEARCH AND BUSINESS DEVELOPMENT FOUNDATION, Pohang-si (KR)

(72) Inventors: Yong-Young NOH, Pohang-si (KR); Jaeyun LEE, Pohang-si (KR)

(73) Assignee: POSTECH RESEARCH AND BUSINESS DEVELOPMENT FOUNDATION, Pohang-si (KR)

(21) Appl. No.: 19/420,933

(22) Filed: Dec. 16, 2025

(30) Foreign Application Priority Data
Dec. 20, 2024 (KR) 10-2024-0192806
Nov. 20, 2025 (KR) 10-2025-0177371

(51) Int. Cl. H10D 30/67; C23C 14/06; C23C 14/24; C23C 14/58; H10P 14/20; H10P 95/90

(52) U.S. Cl. CPC H10D 30/675; C23C 14/0623; C23C 14/24; C23C 14/5806; H10P 14/3414; H10P 95/90

(57) ABSTRACT

Disclosed is a method for manufacturing indium monoselenide semiconductor thin film for fabricating large-area thin film transistor. The present disclosure provides the method for manufacturing an indium monoselenide semiconductor thin film, the method comprising: (a) depositing a deposition source including an indium selenide (InSe) on a substrate using a thermal evaporation method, thus preparing a first indium monoselenide semiconductor thin film including a first indium monoselenide (InSe); and (b) annealing the first indium monoselenide semiconductor thin film, thus preparing a second indium monoselenide semiconductor thin film including a second indium monoselenide (InSe). The indium monoselenide semiconductor thin film according to the present disclosure can be applied to large-area thin film transistors, and the large-area thin film transistors including the indium monoselenide semiconductor thin film according to the present disclosure can be applied in circuits.

### CROSS REFERENCE TO RELATED APPLICATION

The present application claims priority to Korean Patent Application No. 10-2024-0192806, filed Dec. 20, 2024, and Korean Patent Application No. 10-2025-0177371, filed Nov. 20, 2025, the entire contents of which are incorporated herein for all purposes by these references.

### BACKGROUND OF THE DISCLOSURE

### 1. Field of the Disclosure

The present disclosure relates to a method for manufacturing indium monoselenide semiconductor thin film for fabricating large-area thin film transistor.

### 2. Description of the Related Art

Indium monoselenide (InSe) has recently attracted attention as a two-dimensional (2D) semiconductor material, and its excellent electron mobility and outstanding optical properties make it a promising candidate for electronic and optoelectronic devices. InSe has an atomic-level thin layered structure, thus exhibiting electronic and optical properties that are differentiated from those of conventional three-dimensional semiconductors. These characteristics are primarily attributed to quantum entanglement and quantum confinement effects, and InSe exhibits unique electronic phenomena, such as the quantum Hall effect, thus presenting new possibilities as an electronic material. In particular, InSe exhibits an extremely high electron mobility of over 10³ cm²/V·s even in thin structures consisting of a few-layer structures, and this value increases to 10⁴ cm²/V·s at a liquid helium temperature. This value is significantly higher than that of conventional two-dimensional transition metal chalcogenides (TMDCs), demonstrating the potential for outstanding performance in high-speed electronic devices and transistors. Due to these properties, InSe is considered a highly promising material for the development of various electronic and optoelectronic devices such as high-speed transistors, optoelectronic devices, and ultra-precision sensors. In addition, as a material with polymorphism, it can have two crystal structures, the β (beta) phase and the γ (gamma) phase, thus allowing for the implementation of a variety of physical and electronic properties. However, there are still significant limitations in the large-area synthesis and efficient manufacturing process of InSe. The currently used chemical vapor deposition (CVD) and mechanical exfoliation methods have limitations in the production of large-area InSe thin films, which can constitute a significant obstacle to commercialization.

Therefore, in order to apply InSe to large-scale electronic and optoelectronic devices, optimization of synthesis technology and process is essential, and continuous research and technological development are required for this purpose.

### SUMMARY OF THE DISCLOSURE

The purpose of the present disclosure is to solve the above problems, and to provide a high-performance n-channel transistor using indium monoselenide as a semiconductor layer by utilizing thermal evaporation deposition technology, at the same time to provide a large-area thin-film transistor with excellent reproducibility.

In addition, another purpose of the present disclosure is to provide an n-type InSe semiconductor thin film having a β-phase crystal structure using thermal evaporation deposition technology.

The present disclosure provides a method for manufacturing an indium monoselenide semiconductor thin film, the method comprising: (a) depositing a deposition source including an indium selenide (InSe) on a substrate using a thermal evaporation method, thus preparing a first indium monoselenide semiconductor thin film including a first indium monoselenide (InSe); and (b) annealing the first indium monoselenide semiconductor thin film, thus preparing a second indium monoselenide semiconductor thin film including a second indium monoselenide (InSe).

In addition, the deposition in step (a) may be carried out at a temperature of the substrate in the range of 20 to 40° C., preferably at room temperature.

In addition, the pressure before the thermal evaporation in step (a) may be in a range of vacuum to 5×10⁻³ torr, preferably vacuum to 5×10⁻⁷ torr.

In addition, the first indium monoselenide of the first indium monoselenide semiconductor thin film may be amorphous.

In addition, a thickness of the first indium monoselenide semiconductor thin film of step (a) may be in the range of 1.5 to 10 nm, preferably 4 to 6 nm.

In addition, the substrate of step (a) may comprise at least one selected from the group consisting of silicon, n-doped silicon (n-doped Si), p-doped silicon (p-doped Si), silicon dioxide stacked with n-doped silicon (n−−Si/SiO₂), silicon dioxide stacked with p-doped silicon (p++Si/SiO₂), polyimide (PI), and polyamide.

In addition, the substrate may comprise a gate electrode and an insulating layer stacked on the gate electrode.

In addition, the gate electrode may comprise at least one selected from the group consisting of n-doped silicon (n-doped Si), p-doped silicon (p-doped Si), gold (Au), silver (Ag), platinum (Pt), titanium (Ti), aluminum (Al), tungsten (W), magnesium (Mg), calcium (Ca), ytterbium (Yb), chromium (Cr), nickel (Ni), molybdenum (Mo), gold oxide, platinum oxide, silver oxide, palladium oxide, iron oxide, graphene, carbon nanotube (CNT), silver nanowire (Ag NW), indium tin oxide, and poly(3,4-ethylenedioxythiophene) polystyrene sulfonate (PEDOT:PSS).

In addition, the insulating layer may comprise at least one selected from the group consisting of silicon dioxide, glass, quartz, alumina, silicon carbide, magnesium oxide, polyethylene naphthalate (PEN), polyethylene terephthalate (PET), polystyrene (PS), polyimide (PI), polyvinyl chloride (PVC), polyvinyl pyrrolidone (PVP), polyethylene (PE), silicon oxide (SiO₂), germanium, polyvinyl alcohol (PVA), polymethyl methacrylate (PMMA), zirconium oxide (ZrO₂), aluminum oxide (AlO₂), and hafnium oxide (HfO₂).

In addition, the annealing of step (b) may be carried out at a temperature in a range of 310 to 410° C., preferably 380 to 400° C.

In addition, the annealing of step (b) may be carried out for 10 to 60 minutes, preferably 20 to 40 minutes.

In addition, the second indium monoselenide of the second indium monoselenide semiconductor thin film of step (b) may have a β phase.

In addition, the second indium monoselenide of the second indium monoselenide semiconductor thin film of step (b) may have a layered structure.

In addition, the second indium monoselenide of the second indium monoselenide semiconductor thin film of step (b) may be an n-type semiconductor.

In addition, the method, after step (b), may further comprise; (c) a source electrode and a drain electrode may be formed on the second indium monoselenide semiconductor thin film, respectively.

In addition, the source electrode and the drain electrode each may comprise at least one selected from the group consisting of gold (Au), silver (Ag), platinum (Pt), titanium (Ti), aluminum (Al), tungsten (W), magnesium (Mg), calcium (Ca), ytterbium (Yb), chromium (Cr), nickel (Ni), molybdenum (Mo), gold oxide, platinum oxide, silver oxide, palladium oxide, iron oxide, graphene, carbon nanotubes (CNT), silver nanowires (Ag NW), indium tin oxide, and poly(3,4-ethylenedioxythiophene) polystyrene sulfonate (PEDOT:PSS).

The thin film transistor (TFT) based on the β-phase InSe channel layer according to the present disclosure has the effect of realizing excellent electrical performance as well as excellent output and transfer characteristics, based on high electron field effect mobility and excellent on/off current ratio.

In addition, the indium monoselenide semiconductor thin film according to the present disclosure can be applied to large-area thin film transistors.

In addition, the large-area thin film transistors including the indium monoselenide semiconductor thin film according to the present disclosure can be applied in circuits.

### BRIEF DESCRIPTION OF THE DRAWINGS

Since the accompanying drawings are for reference in describing exemplary embodiments of the present disclosure, the technical spirit of the present disclosure should not be construed as being limited to the accompanying drawings.

FIG. 1 is a schematic diagram showing the structure of β-phase InSe.

FIG. 2 shows X-ray diffraction characteristics of the InSe thin film formed in Example 1-4 before and after annealing.

FIG. 3 is the results of UV-Vis spectroscopy of the InSe thin film formed in Example 1-4.

FIGS. 4A and 4B are Raman spectroscopy results of the InSe thin film formed in Example 1-4 before and after annealing, respectively.

FIGS. 5A to 5F show the transfer characteristics of TFTs formed in Examples 1-1 to 1-6, respectively.

FIG. 5G shows the performance of TFTs formed in Examples 1-1 to 1-6, respectively as a function of annealing temperature.

FIG. 6 shows the output characteristic curve of TFTs formed in Example 1-4.

FIGS. 7A to 7C show the transfer characteristics of TFTs formed in Examples 2-1 to 2-3, respectively.

FIG. 7D shows the electron mobility and on/off ratio trends as a function of InSe film thickness.

FIG. 8A shows the cross-sectional characteristics of a 5 nm InSe film formed in Example 1-4 using a transmission electron microscope.

FIG. 8B shows the cross-sectional characteristics of a 3 nm InSe film formed in Example 2-1 using a transmission electron microscope.

FIG. 9 shows the cross-sectional characteristics of the 5 nm InSe thin film formed in Examples 1-4, analyzed using a scanning transmission electron microscope.

FIG. 10A shows the device transfer characteristics of a 24×24 InSe thin film transistor array formed on a 4-inch SiO₂ substrate of Example 3-1.

FIG. 10B shows the performance of all devices in FIG. 10A in the form of a histogram, showing the distribution of mobility (μ_{FE}), driving voltage (V_{TH}), and subthreshold swing (SS) of Example 3-1.

FIG. 11 shows the driving characteristics of an inverter of Example 4-1 formed by complementarily combining the n-type 5 nm InSe thin film transistor formed in Examples 1-4 with a p-type TeSeOₓ semiconductor.

### DESCRIPTION OF THE PREFERRED EMBODIMENTS

Herein after, examples of the present disclosure will be described in detail with reference to the accompanying drawings in such a manner that the ordinarily skilled in the art can easily implement the present disclosure.

The description given below is not intended to limit the present disclosure to specific embodiments. In relation to describing the present disclosure, when the detailed description of the relevant known technology is determined to unnecessarily obscure the gist of the present disclosure, the detailed description may be omitted.

The terminology used herein is for the purpose of describing particular embodiments only and is not intended to limit the scope of the present disclosure. As used herein, the singular forms “a”, “an”, and “the” are intended to include the plural forms as well unless the context clearly indicates otherwise. In the present disclosure, the terms “comprise”, “include” or “have” are intended to designate the existence of features, numbers, steps, actions, components, operations, elements and/or combinations thereof as stated in the specification, and should be understood not to preclude the existence or addition of one or more other of features, numbers, steps, actions, components, operations, elements and/or combinations thereof.

Terms including ordinal numbers used in the specification, “first”, “second”, etc. can be used to discriminate one component from another component, but the order or priority of the components is not limited by the terms unless specifically stated. These terms are used only for the purpose of distinguishing a component from another component. For example, without departing from the scope of the present disclosure, a first component may be referred as a second component, and similarly a second component may also be referred to as a first component.

In addition, when it is mentioned that a component is “formed” or “stacked” on another component, it should be understood such that one component may be directly attached to or directly stacked on the front surface or one surface of the other component, or an additional component may be disposed between them.

Hereinafter, a method for manufacturing indium monoselenide semiconductor thin film for fabricating large-area thin film transistor will be described in detail. However, those are described as examples, and the present disclosure is not limited thereto and is only defined by the scope of the appended claims.

The present disclosure provides a method for manufacturing an indium monoselenide semiconductor thin film, the method comprising: (a) depositing a deposition source including an indium selenide (InSe) on a substrate using a thermal evaporation method, thus preparing a first indium monoselenide semiconductor thin film including a first indium monoselenide (InSe); and (b) annealing the first indium monoselenide semiconductor thin film, thus preparing a second indium monoselenide semiconductor thin film including a second indium monoselenide (InSe).

In addition, the deposition in step (a) may be carried out at a temperature of the substrate in the range of 20 to 40° C., preferably at room temperature. When the deposition of step (a) is carried out at a temperature of less than 20° C., surface diffusion is insufficient, which inhibits crystal growth and increases compositional deviation with amorphous components, resulting in non-uniform device characteristics, which is undesirable. When the deposition of step (a) is carried out at a temperature exceeding 40° C., a compositional imbalance occurs due to a difference in vapor pressures of indium and selenium, which easily forms an indium-rich or selenium-deficient composition, and accordingly, abnormal phases or defect levels increase, resulting in deterioration of electrical characteristics, which is undesirable.

In addition, the pressure before the thermal evaporation in step (a) may be in a range of vacuum to 5×10⁻³ torr, preferably a vacuum to 5×10⁻⁷ torr. When the pressure before the thermal evaporation in step (a) exceeds 5×10⁻³ torr, oxidation reactions due to residual oxygen, moisture and impurities, and collision scattering of evaporated species, increase, thereby deteriorating the composition and crystallinity of the film, which is undesirable.

In addition, the first indium monoselenide of the first indium monoselenide semiconductor thin film may be amorphous.

In addition, a thickness of the first indium monoselenide semiconductor thin film of step (a) may be in the range of 1.5 to 10 nm, preferably 4 to 6 nm. When the thickness of the first indium monoselenide semiconductor thin film in step (a) is less than 1.5 nm, the film is directly affected by substrate roughness and interfacial defects, resulting in increased leakage current and threshold voltage instability. Consequently, film continuity and charge transport pathways are not secured, leading to unstable device operation, which is undesirable. When the thickness exceeds 10 nm, the gate controllability of the electric field in the carrier channel decreases, making charge accumulation and depletion inefficient, and thereby causing increase of threshold voltage and decrease of the on/off ratio, which is undesirable.

In addition, the substrate of step (a) may comprise at least one selected from the group consisting of silicon, n-doped silicon (n-doped Si), p-doped silicon (p-doped Si), silicon dioxide stacked with n-doped silicon (n×−Si/SiO₂), silicon dioxide stacked with p-doped silicon (p++Si/SiO₂), polyimide (PI), and polyamide.

In addition, the substrate may comprise a gate electrode and an insulating layer stacked on the gate electrode.

In addition, the gate electrode may comprise at least one selected from the group consisting of n-doped silicon (n-doped Si), p-doped silicon (p-doped Si), gold (Au), silver (Ag), platinum (Pt), titanium (Ti), aluminum (Al), tungsten (W), magnesium (Mg), calcium (Ca), ytterbium (Yb), chromium (Cr), nickel (Ni), molybdenum (Mo), gold oxide, platinum oxide, silver oxide, palladium oxide, iron oxide, graphene, carbon nanotube (CNT), silver nanowire (Ag NW), indium tin oxide, and poly(3,4-ethylenedioxythiophene) polystyrene sulfonate (PEDOT:PSS).

In addition, the insulating layer may comprise at least one selected from the group consisting of silicon dioxide, glass, quartz, alumina, silicon carbide, magnesium oxide, polyethylene naphthalate (PEN), polyethylene terephthalate (PET), polystyrene (PS), polyimide (PI), polyvinyl chloride (PVC), polyvinyl pyrrolidone (PVP), polyethylene (PE), silicon oxide (SiO₂), germanium, polyvinyl alcohol (PVA), polymethyl methacrylate (PMMA), zirconium oxide (ZrO₂), aluminum oxide (AlO₂), and hafnium oxide (HfO₂).

In addition, the annealing of step (b) may be carried out at a temperature in a range of 310 to 410° C., preferably 380° C. to 400° C. When the annealing in step (b) is carried out at a temperature lower than 310° C., crystal growth does not proceed, resulting in decrease of crystallinity, which is undesirable. When the annealing in step (b) is carried out at a temperature higher than 430° C., excessive heat causes interlayer decomposition, chalcogen compound desorption (S/Se desorption), increase in surface roughness, and interfacial reactions, thereby damaging the composition and structure of the thin film, which is undesirable.

In addition, the annealing of step (b) may be carried out for 10 to 60 minutes, preferably 20 to 40 minutes.

When the annealing in step (b) is carried out for less than 10 minutes, insufficient annealing limits atomic diffusion and rearrangement within the crystal, resulting in residual stress in the thin film. As a result, grain growth and interlayer alignment are not sufficiently achieved, leading to the formation of a thin film with low crystallinity and a high defect density, which is undesirable. When the annealing in step (b) is carried out for more than 60 minutes, excessive grain growth and interlayer agglomeration occur, leading to increased surface roughness and reduced film uniformity, as well as selenium (Se) desorption and compositional imbalance, which can result in the formation of an indium-rich phase or abnormal phases (such as indium oxide), thereby deteriorating electrical properties, which is undesirable.

In addition, the second indium monoselenide of the second indium monoselenide semiconductor thin film of step (b) may be crystalline.

In addition, the second indium monoselenide of the second indium monoselenide semiconductor thin film of step (b) may have a β phase.

In addition, the second indium monoselenide of the second indium monoselenide semiconductor thin film of step (b) may have a layered structure.

In addition, the second indium monoselenide of the second indium monoselenide semiconductor thin film of step (b) may be an n-type semiconductor.

In addition, the method, after step (b), may further comprise; (c) a source electrode and a drain electrode may be formed on the second indium monoselenide semiconductor thin film, respectively.

In addition, the source electrode and the drain electrode each may comprise at least one selected from the group consisting of gold (Au), silver (Ag), platinum (Pt), titanium (Ti), aluminum (Al), tungsten (W), magnesium (Mg), calcium (Ca), ytterbium (Yb), chromium (Cr), nickel (Ni), molybdenum (Mo), gold oxide, platinum oxide, silver oxide, palladium oxide, iron oxide, graphene, carbon nanotubes (CNT), silver nanowires (Ag NW), indium tin oxide, and poly(3,4-ethylenedioxythiophene) polystyrene sulfonate (PEDOT:PSS).

### Examples

Hereinafter, examples of the present disclosure will be described. However, the examples are for illustrative purposes, and the scope of the present disclosure is not limited by the examples.

### Example: Fabrication of n-Channel Thin Film Transistor Using Thermal Evaporation Deposition Process

### Example 1: Variation Of Annealing Temperature (Semiconductor Thin Film Thickness: 5 nm)

### Example 1-1: 310° C.

For deposition of an InSe semiconductor thin film, commercially available InSe powder with a purity of 99% or higher was used as the evaporation source. The film was deposited using a conventional thermal evaporation apparatus, with a p++Si/SiO₂ substrate, and the temperature of the substrate maintained at 25° C. Before evaporation, the vacuum level of the chamber was less than 10⁻³ Torr, and the distance between the substrate and the boat containing the InSe powder was set in the range of 2 to 50 cm. The deposition rate was 0.2 Å/s. The thickness of the InSe film was monitored in real time during deposition, and was 5 nm. The deposited sample was then subjected to an annealing process at a temperature of 310° C. for 0.5 hours in a nitrogen (N₂) atmosphere glove box, thereby forming an n-type InSe semiconductor thin film. Subsequently, gold (Au) was deposited by thermal evaporation as source and drain electrodes to complete fabrication of the thin film transistor (TFT).

### Example 1-2: 346° C.

The thin film transistor (TFT) was fabricated in the same manner as in Example 1-1, except that the annealing was carried out at a temperature of 346° C. instead of 310° C.

### Example 1-3: 380° C.

The thin film transistor (TFT) was fabricated in the same manner as in Example 1-1, except that the annealing was carried out at a temperature of 380° C. instead of 310° C.

### Example 1-4: 390° C.

The thin film transistor (TFT) was fabricated in the same manner as in Example 1-1, except that the annealing was carried out at a temperature of 390° C. instead of 310° C.

### Example 1-5: 410° C.

The thin film transistor (TFT) was fabricated in the same manner as in Example 1-1, except that the annealing was carried out at a temperature of 410° C. instead of 310° C.

### Example 1-6: 425° C.

The thin film transistor (TFT) was fabricated in the same manner as in Example 1-1, except that the annealing was carried out at a temperature of 425° C. instead of 310° C.

### Example 2: Variation of Semiconductor Thin Film Thickness

### Example 2-1: 3 nm

For deposition of an InSe semiconductor thin film, commercially available InSe powder with a purity of 99% or higher was used as the evaporation source. The film was deposited using a conventional thermal evaporation apparatus, with a p++Si/SiO₂ substrate, and the temperature of the substrate maintained at 25° C. Before evaporation, the vacuum level of the chamber was less than 10⁻³ Torr, and the distance between the substrate and the boat containing the InSe powder was set in the range of 2 to 50 cm. The deposition rate was 0.2 Å/s. The thickness of the InSe film was monitored in real time during deposition, and was 3 nm. The deposited sample was then subjected to an annealing process at a temperature of 390° C. for 0.5 hours in a nitrogen (N₂) atmosphere glove box. Subsequently, gold (Au) was deposited by thermal evaporation as source and drain electrodes to complete fabrication of the thin film transistor (TFT).

### Example 2-2: 7 m

The thin film transistor (TFT) was fabricated in the same manner as in Example 2-1, except that the semiconductor thin film was formed with a thickness of 7 nm instead of 3 nm.

### Example 2-3: 10 nm

The thin film transistor (TFT) was fabricated in the same manner as in Example 2-1, except that the semiconductor thin film was formed with a thickness of 10 nm instead of 3 nm.

### Example 3-1: Large-Area InSe Thin Film Transistor

A stencil mask having a 24×24 array of InSe thin film transistors was attached to a 4-inch p++Si/SiO₂ substrate, and a patterned InSe thin film was deposited on the 4-inch substrate in the same manner as described in Example 1-4. Subsequently, gold (Au) was deposited as source and drain electrodes by thermal evaporation using a stencil mask for the source/drain electrodes, thereby completing fabrication of the large-area InSe thin film transistor (TFT).

Example 4-1: Circuit Utilizing InSe Thin Film Transistor

An inverter was fabricated by complementarily combining an n-type 5 nm InSe thin film transistor with a p-type TeSeOₓ semiconductor. Specifically, after forming the n-type InSe thin film on a 4-inch p++Si/SiO₂ substrate using the same method described in Example 1-4, the deposition of the TeSeOₓ semiconductor film aligned with the n-type InSe thin film was carried out by evaporating a mixture of commercially available TeO₂ powder and Se powder with a purity of 99% or higher. The raw material mixture of 40 mg of TeO₂ powder and 11 mg of Se powder was placed in a boat. The substrate temperature was maintained at 25° C., and the vacuum level of the chamber before evaporation was less than 10⁻³ Torr. The distance between the substrate and the boat containing the mixed powder of TeO₂ and Se was set in the range of 2 to 50 cm. The deposition rate was 0.2 to 3.0 Å/s, and the thickness of the TeSeOₓ film was monitored in real time during deposition, resulting in a thickness of 20 nm. The deposited sample was first annealed at a temperature of 225° C. for 0.5 hours in a nitrogen (N₂) atmosphere glove box to induce compositional stabilization and interfacial bonding. Subsequently, gold (Au) was deposited as source and drain electrodes, thereby fabricating an inverter device in which the n-type InSe thin film transistor and the p-type TeSeOₓ semiconductor were complementarily combined.

### Test Example

### Test Example 1: X-Ray Diffraction (XRD) Analysis of InSe Thin Film

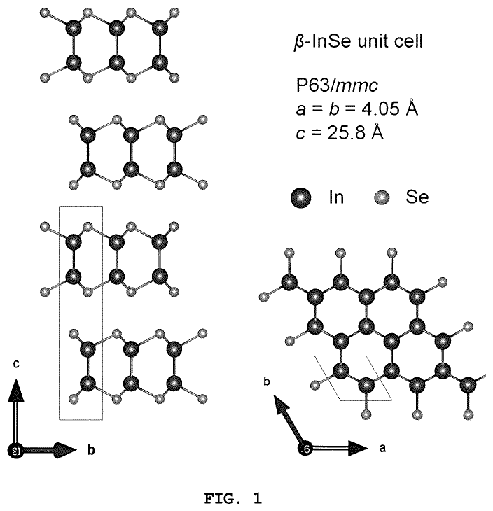

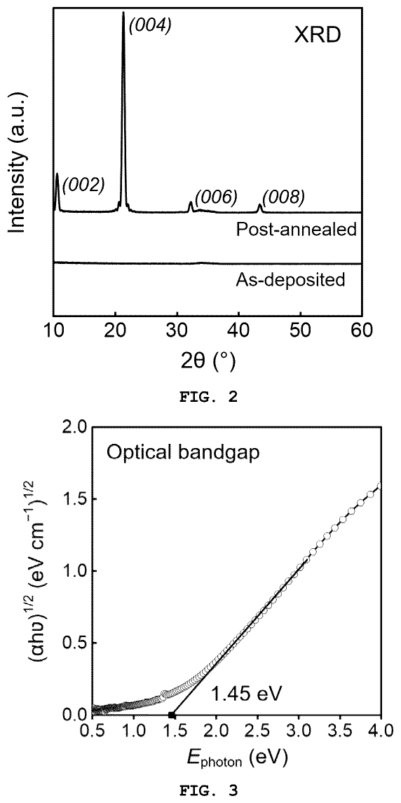

FIG. 1 is a schematic diagram showing the structure of β-phase InSe, and FIG. 2 shows the X-ray diffraction characteristics of the InSe thin film formed in Example 1-4 before and after annealing.

Referring to FIGS. 1 and 2, the XRD results of the InSe thin film formed in Example 1-4 of the present invention indicate that, before annealing, the film was in an amorphous state with no observable peaks. After annealing, however, the characteristic XRD peaks of β-phase InSe, namely (002), (004), (006), and (008), were observed.

### Test Example 2: Ultraviolet-Visible Spectroscopy Analysis of InSe Thin Film

FIG. 3 shows the results of UV-Vis spectroscopy of the InSe thin film formed in Example 1-4.

Referring to FIG. 3, as a result of ultraviolet-visible spectroscopy and the extracted bandgap analysis of the InSe thin film formed in Example 1-4, it was confirmed that the thermally evaporated InSe exhibited a semiconductor characteristic bandgap of 1.45 eV.

### Test Example 3: Raman Spectroscopy Analysis of InSe Thin Film

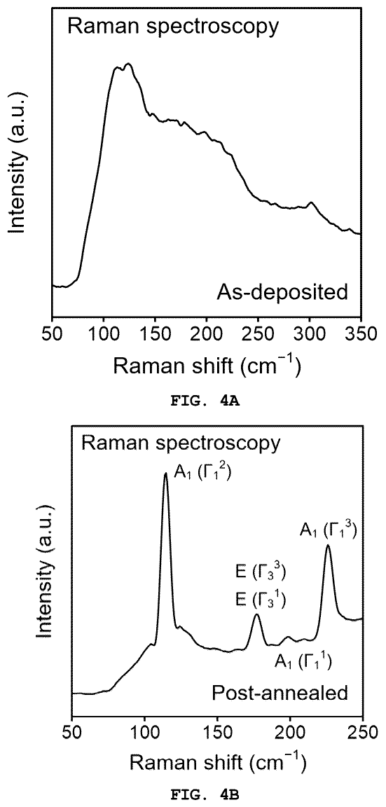

FIG. 4A is Raman spectroscopy results of the InSe thin film formed before annealing in Example 1-4 and FIG. 4B is Raman spectroscopy results of the InSe thin film formed after annealing in Example 1-4.

Referring to FIGS. 4A and 4B, the Raman spectroscopy characteristics of the InSe thin film before and after annealing are shown, respectively. In the case of the film before annealing, no peaks related to InSe were observed. In contrast, after annealing, the characteristic peaks of β-phase InSe at 115, 178, 198, 226, and 301 cm⁻¹ were confirmed.

### Test Example 4: Transfer Characteristics of TFTs Depending on Annealing Temperature

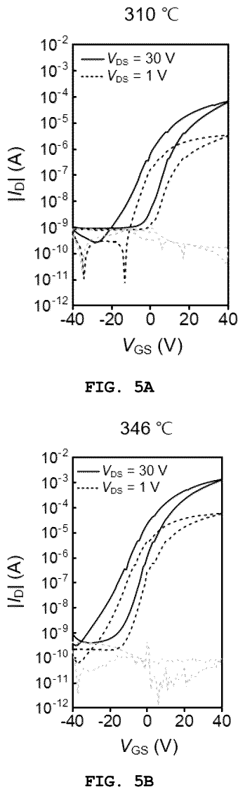

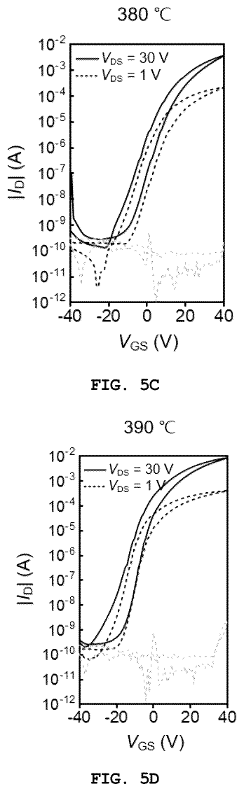

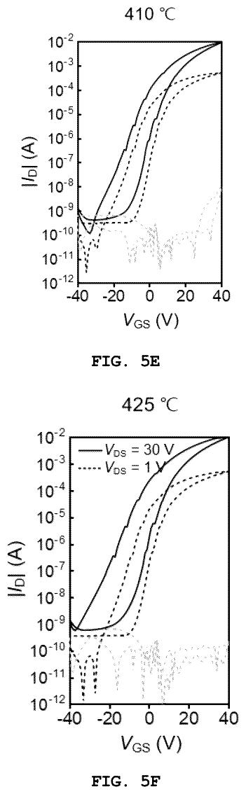

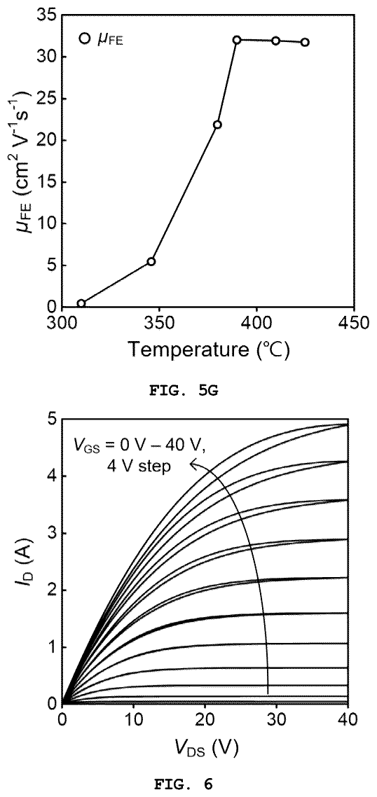

FIGS. 5A to 5F are respectively the transfer curves (I_{D}-V_{GS}) of the TFTs corresponding to Examples 1-1 to 1-6, and show V_{DS}=1 V (dotted line) and 30 V (solid line) and FIG. 5G shows the performance of TFTs formed in Examples 1-1 to 1-6, respectively as a function of annealing temperature.

Referring to FIGS. 5A to 5G, the highest electron mobility of 32 cm²/V·s was confirmed at an annealing temperature of 390° C.

### Test Example 5: Output Characteristics of Transistor

FIG. 6 is the output curves (I_{D}-V_{DS}) of the TFT according to Example 1-4, and shows the output characteristics representing measured drain current (I_{D}) by varying the gate voltage (V_{GS}) from 0 V to 40 V in 4 V increments.

Referring to FIG. 6, it was confirmed that the drain current (I_{D}) linearly increased as the gate voltage (V_{GS}) increased, and then the n-type transistor formed a saturation region, thus exhibiting the normal output characteristics. These results confirmed that the InSe thin film had uniform n-type conductivity characteristics, that the charge density in the channel was smoothly controlled according to the gate voltage, and that good ohmic contact was formed with the source and drain electrodes.

### Test Example 6: Analysis Depending on InSe Thin Film Thickness

### Test Example 6-1: Transfer Characteristics of Transistor

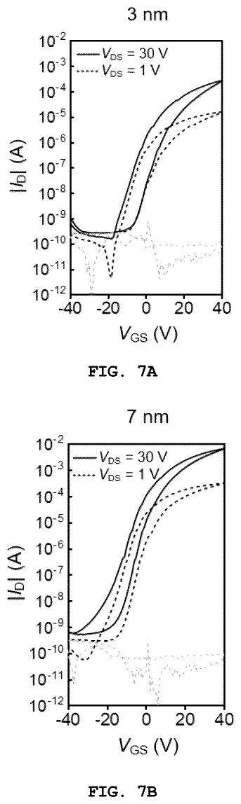

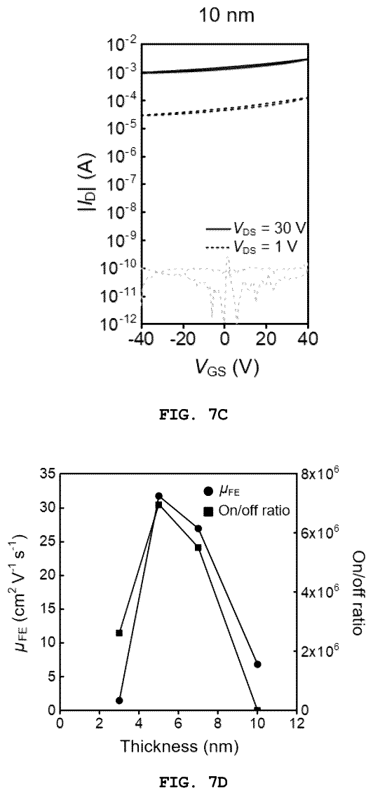

FIGS. 7A to 7C are the transfer curves (I_{D}-V_{GS}) of the TFTs according to Examples 2-1 to 2-3, respectively, and show V_{DS}=1 V (dotted line) and 30 V (solid line). FIG. 7D shows the trend of electron mobility and on/off ratio according to the thickness of the InSe thin film.

Referring to FIGS. 7A to 7D, it was confirmed that the 5 nm InSe TFT showed the highest mobility and on/off ratio.

### Test Example 6-2: Transmission Electron Microscopy (TEM) Analysis

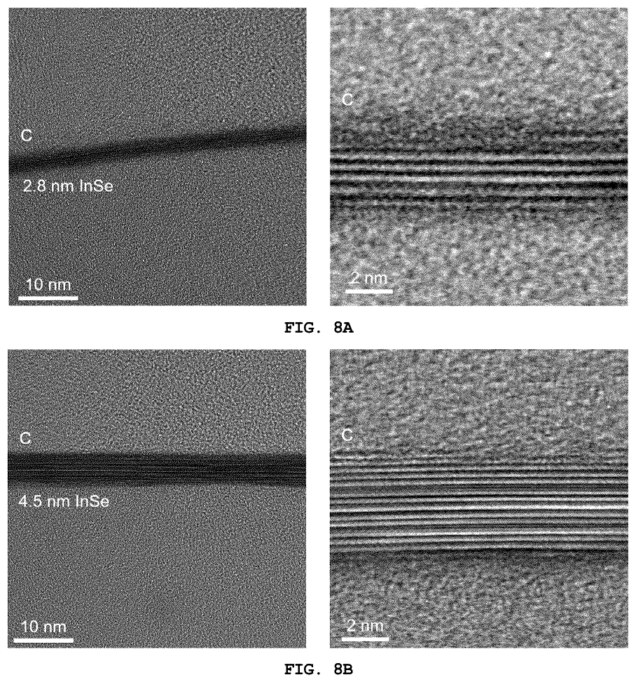

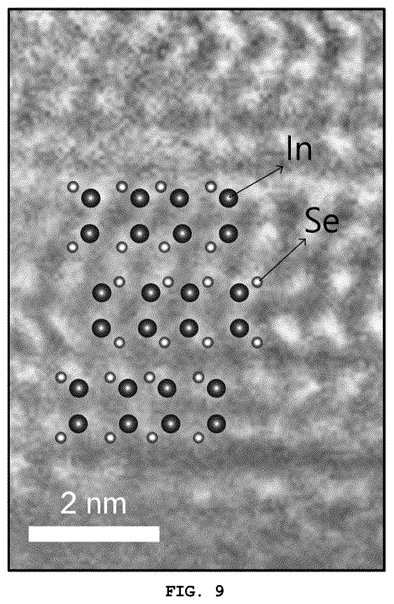

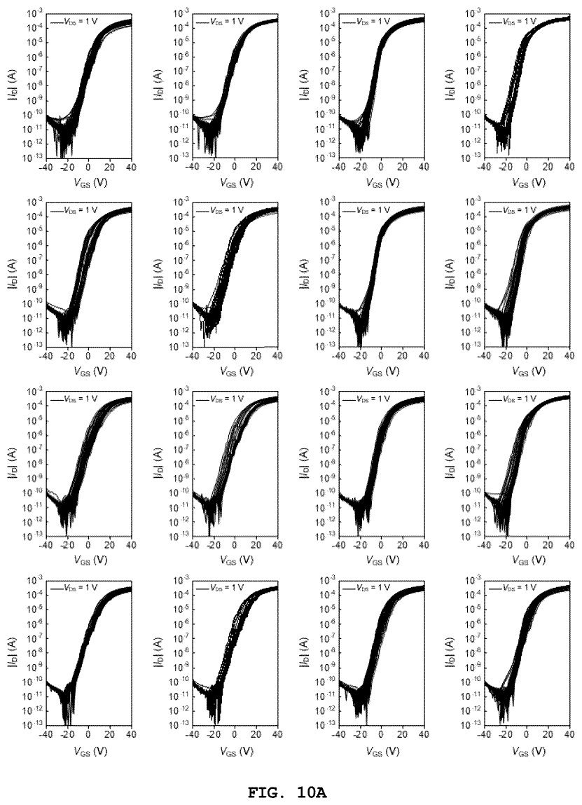

FIG. 8A shows the cross-sectional characteristics of a 5 nm InSe thin film formed in Example 1-4, and FIG. 8B shows the cross-sectional characteristics of a 3 nm InSe thin film formed in Example 2-1 using a transmission electron microscope.

Referring to FIGS. 8A and 8B, it was confirmed that the 5 nm thin film had an actual thickness of 4.5 nm, and the 3 nm thin film had an actual thickness of 2.8 nm through the annealing process, and both had a layered structure.

### Test Example 6-3: Scanning Transmission Electron Microscopy (STEM) Analysis

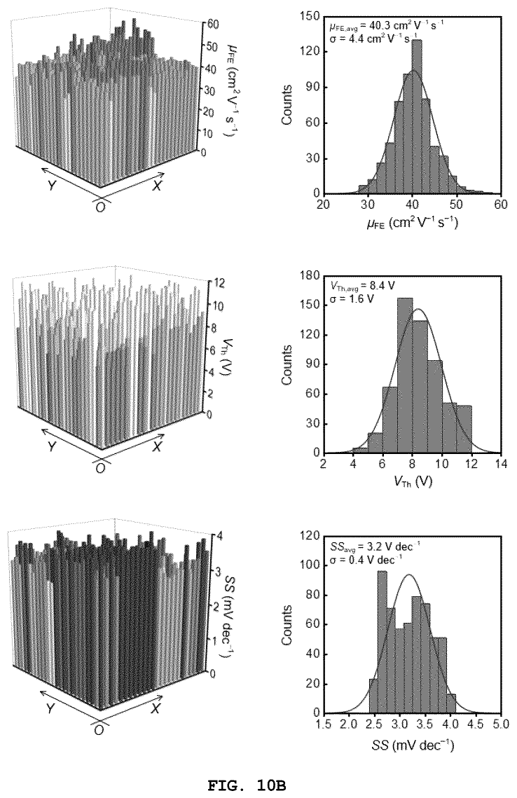

FIG. 9 shows the cross-sectional characteristics of the 5 nm InSe thin film formed in Example 1-4 using a scanning transmission electron microscopy.

Referring to FIG. 9, it was confirmed that the atomic arrangement of In and Se exists in the form of a layered structure, which is consistent with the previous thin film analysis results.

### Test Example 7: Operation of Large-Area InSe Thin Film Transistor

FIG. 10A shows the device transfer characteristics of a 24×24 InSe thin film transistor array formed on a 4-inch SiO₂ substrate of Example 3-1, and FIG. 10B shows the performance of all devices in FIG. 10A showing the distribution of mobility (μ_{FE}), driving voltage (V_{TH}), and subthreshold swing (SS) of Example 3-1 in the form of a histogram.

Referring to FIGS. 10A and 10B, characteristics of uniform large-area were confirmed.

### Test Example 8: Circuit Application Utilizing InSe Thin Film Transistor

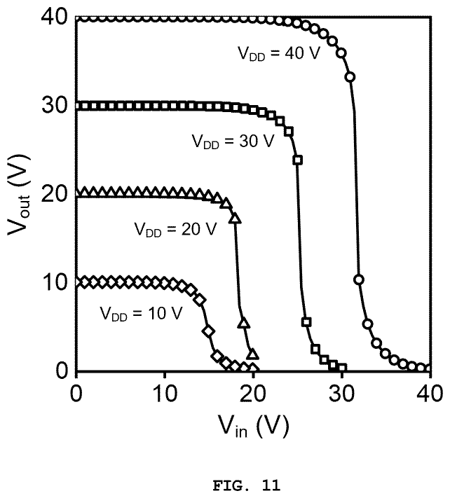

FIG. 11 shows the driving characteristics of an inverter of Example 4-1 formed by complementarily combining an n-type 5 nm InSe thin film transistor, formed in Example 1-4, with a p-type TeSeOₓ semiconductor.

Referring to FIG. 11, it was confirmed that InSe thin film transistor formed by thermally evaporation can be applied to the inverter circuit, which is the most important unit of the circuit, and it was confirmed that it can be operated with low power while securing sufficient voltage gain and noise margin.

The scope of the present disclosure is defined by the following claims rather than the above detailed description, and all changes or modifications derived from the meaning and scope of the claims and their equivalent concepts should be interpreted as falling into the scope of the present disclosure.

What is claimed is:

1. A method for manufacturing an indium monoselenide semiconductor thin film, the method comprising:
(a) depositing a deposition source including an indium selenide (InSe) on a substrate using a thermal evaporation method, thus preparing a first indium monoselenide semiconductor thin film including a first indium monoselenide (InSe); and
(b) annealing the first indium monoselenide semiconductor thin film, thus preparing a second indium monoselenide semiconductor thin film including a second indium monoselenide (InSe).

2. The method of claim 1, wherein the deposition in step (a) is carried out at a temperature of the substrate in the range of 20 to 40° C.

3. The method of claim 1, wherein the pressure before the thermal evaporation in step (a) is in a range of vacuum to 5×10⁻³ torr.

4. The method of claim 1, wherein the first indium monoselenide of the first indium monoselenide semiconductor thin film is amorphous.

5. The method of claim 1, wherein a thickness of the first indium monoselenide semiconductor thin film of step (a) is in the range of 1.5 to 10 nm.

6. The method of claim 1, wherein the substrate of step (a) comprises at least one selected from the group consisting of silicon, n-doped silicon (n-doped Si), p-doped silicon (p-doped Si), silicon dioxide stacked with n-doped silicon (n−−Si/SiO₂), silicon dioxide stacked with p-doped silicon (p++Si/SiO₂), polyimide (PI), and polyamide.

7. The method of claim 1, wherein the substrate comprises a gate electrode and an insulating layer stacked on the gate electrode.

8. The method of claim 7, wherein the gate electrode comprises at least one selected from the group consisting of n-doped silicon (n-doped Si), p-doped silicon (p-doped Si), gold (Au), silver (Ag), platinum (Pt), titanium (Ti), aluminum (Al), tungsten (W), magnesium (Mg), calcium (Ca), ytterbium (Yb), chromium (Cr), nickel (Ni), molybdenum (Mo), gold oxide, platinum oxide, silver oxide, palladium oxide, iron oxide, graphene, carbon nanotube (CNT), silver nanowire (Ag NW), indium tin oxide, and poly(3,4-ethylenedioxythiophene) polystyrene sulfonate (PEDOT:PSS).

9. The method of claim 7, wherein the insulating layer comprises at least one selected from the group consisting of silicon dioxide, glass, quartz, alumina, silicon carbide, magnesium oxide, polyethylene naphthalate (PEN), polyethylene terephthalate (PET), polystyrene (PS), polyimide (PI), polyvinyl chloride (PVC), polyvinyl pyrrolidone (PVP), polyethylene (PE), silicon oxide (SiO₂), germanium, polyvinyl alcohol (PVA), polymethyl methacrylate (PMMA), zirconium oxide (ZrO₂), aluminum oxide (AlO₂), and hafnium oxide (HfO₂).

10. The method of claim 1, wherein the annealing of step (b) is carried out at a temperature in a range of 310 to 410° C.

11. The method of claim 1, wherein the annealing of step (b) is carried out for 10 to 60 minutes.

12. The method of claim 1, wherein the second indium monoselenide of the second indium monoselenide semiconductor thin film of step (b) has a β phase.

13. The method of claim 1, wherein the second indium monoselenide of the second indium monoselenide semiconductor thin film of step (b) has a layered structure.

14. The method of claim 1, wherein the second indium monoselenide of the second indium monoselenide semiconductor thin film of step (b) is an n-type semiconductor.

15. The method of claim 1, further comprising, after step (b),
(c) a source electrode and a drain electrode are formed on the second indium monoselenide semiconductor thin film, respectively.

16. The method of claim 15, wherein the source electrode and the drain electrode each comprise at least one selected from the group consisting of gold (Au), silver (Ag), platinum (Pt), titanium (Ti), aluminum (Al), tungsten (W), magnesium (Mg), calcium (Ca), ytterbium (Yb), chromium (Cr), nickel (Ni), molybdenum (Mo), gold oxide, platinum oxide, silver oxide, palladium oxide, iron oxide, graphene, carbon nanotubes (CNT), silver nanowires (Ag NW), indium tin oxide, and poly(3,4-ethylenedioxythiophene) polystyrene sulfonate (PEDOT:PSS).
